(19) United States
(12) Patent Application Publication
(10) Pub. No.: US 2024/0096834 A1
(43) Pub. Date: Mar. 21, 2024

(54) SYSTEM AND METHOD OF BUMP MAP DETERMINATION AND BUMP ARRAY FORMATION

(71) Applicant: Taiwan Semiconductor Manufacturing Company Limited, Hsin-Chu (TW)

(72) Inventors: Shih Hsuan HSU, Hsin-Chu (TW); Chan-Chung CHENG, Kaohsiung (TW); Chun-Chen LIU, Kaohsiung (TW); Cheng-Hung CHEN, Tainan (TW); Peng-Ren CHEN, Hsin-Chu (TW); Wen-Hao CHENG, Hsin-Chu (TW); Jong-l MOU, Hsin-Chu (TW)

(21) Appl. No.: 18/126,767

(22) Filed: Mar. 27, 2023

Related U.S. Application Data
(60) Provisional application No. 63/407,248, filed on Sep. 16, 2022.

(51) Int. Cl. H01L 23/00

(52) U.S. Cl. CPC H01L 24/14; H01L 24/11; H01L 24/13; H01L 24/16; H01L 24/81; H01L 2224/1146; H01L 2224/13111; H01L 2224/13147; H01L 2224/13155; H01L 2224/14177; H01L 2224/16145; H01L 2224/81

(57) ABSTRACT

A method is provided. The method includes determining a first bump map indicative of a first set of positions of bumps. The method includes determining, based upon the first bump map, a first plurality of bump densities associated with a plurality of regions of the first bump map. The method includes smoothing the first plurality of bump densities to determine a second plurality of bump densities associated with the plurality of regions of the first bump map. The method includes determining, based upon the second plurality of bump densities, a second bump map indicative of the first set of positions of the bumps and a set of sizes of the bumps.

### CROSS-REFERENCE TO RELATED APPLICATION

This application claims priority to U.S. Patent Application 63/407,248, titled “SYSTEM AND METHOD OF BUMP MAP DETERMINATION AND BUMP ARRAY FORMATION” and filed on Sep. 16, 2022, which is incorporated herein by reference.

### BACKGROUND

Semiconductor devices are used in a multitude of electronic devices, such as mobile phones, laptops, desktops, tablets, watches, gaming systems, and various other industrial, commercial, and consumer electronics. Semiconductor wafers generally undergo one or more processes to produce semiconductor devices thereon and/or therefrom.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a diagram illustrating a first plurality of bump densities associated with a plurality of regions of a first bump map being determined, in accordance with some embodiments.

FIG. 1B illustrates shapes of bumps of a bump map, in accordance with some embodiments.

FIG. 2 is a diagram illustrating a second plurality of bump densities associated with a plurality of regions of a first bump map being determined, in accordance with some embodiments.

FIG. 3 is a diagram illustrating a bump density of a second plurality of bump densities being determined, in accordance with some embodiments.

FIG. 4 is a diagram illustrating a second bump map being determined based upon a second plurality of bump densities and a first bump map, in accordance with some embodiments.

FIG. 5 is a diagram illustrating a second bump map being used to form a bump array on a wafer, in accordance with some embodiments.

FIG. 6 illustrates a semiconductor device at a stage of fabrication, in accordance with some embodiments.

FIG. 7 illustrates a semiconductor device at a stage of fabrication, in accordance with some embodiments.

FIG. 8A illustrates at least a portion of a first bump map, in accordance with some embodiments.

FIG. 8B illustrates at least a portion of a second bump map, in accordance with some embodiments.

FIGS. 8C and 8D illustrate a semiconductor device at a stage of fabrication, in accordance with some embodiments.

FIG. 9 illustrates a plating process performed to form bumps of a bump array, in accordance with some embodiments.

FIG. 10 is a flow diagram illustrating a method of determining a bump map, in accordance with some embodiments.

FIG. 11 is a flow diagram illustrating a method of determining a bump map, in accordance with some embodiments.

FIG. 12 is a flow diagram illustrating a method of determining a bump map, in accordance with some embodiments.

FIG. 13 is a flow diagram illustrating a method of forming a semiconductor device, in accordance with some embodiments.

FIG. 14 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

A system and method for determining a bump map is provided. A first plurality of bump densities of regions of a second bump map are determined. The first plurality of bump densities is smoothed to determine a second plurality of bump densities. In some embodiments, a uniformity of bump densities of the second plurality of bump densities is higher than a uniformity of bump densities of the first plurality of bump densities. The bump map is determined based upon the second plurality of bump densities and the second bump map. In some embodiments, bumps indicated by the second bump map are resized, based upon the second plurality of bump densities, to determine the bump map. The bump map is used to form a first bump array on a wafer. The first bump array comprises a plurality of bumps, such as micro-bumps. In some embodiments, the first bump array is formed, by a plating system, according to the bump map such that positions of bumps of the first bump array match positions indicated by the bump map and sizes of bumps of the first bump array match sizes indicated by the bump map. Compared to a bump array determined using the second bump map, the first bump array has an increased coplanarity and/or reduced variation in bump heights of bumps, such as due, at least in part, to the bump map that is used to form the first bump array being determined using the second plurality of bump densities that have the higher uniformity than the first plurality of bump densities. The increased coplanarity and/or reduced variation in bump heights of bumps facilitates, among other things, improved yield at least because resulting devices are more uniform, exhibit more consistent, predictable, etc. behavior, etc.

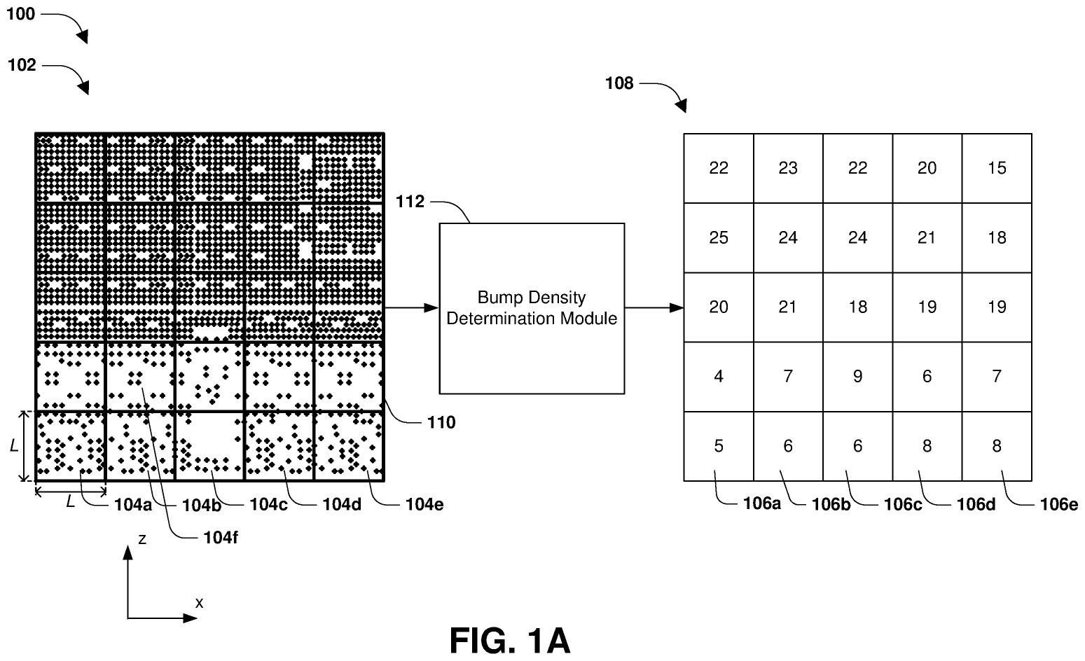

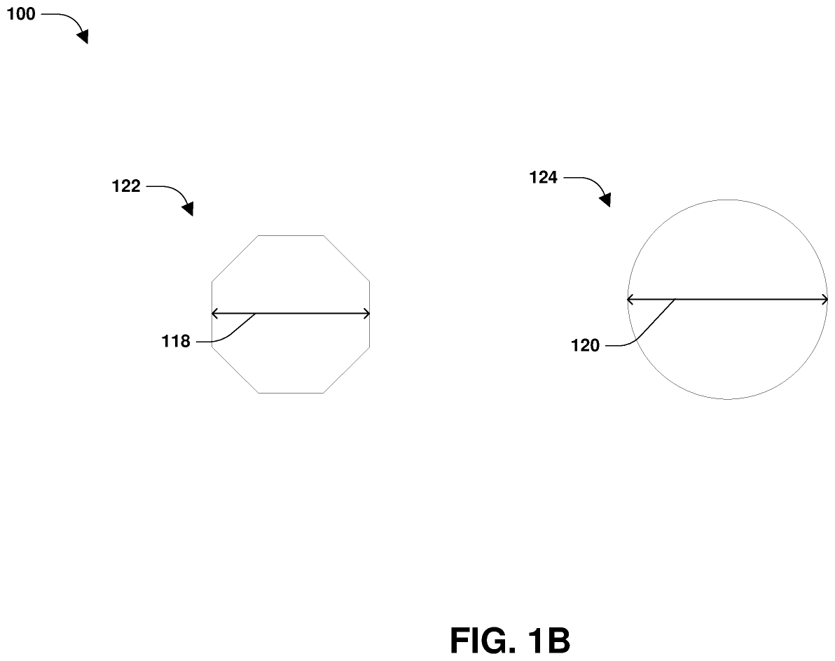

FIGS. 1A-4 illustrate a system 100 for determining bump maps for use in forming bump arrays. With respect to FIG. 1A, a first plurality of bump densities 108 associated with a plurality of regions of a first bump map 102 is determined. In some embodiments, the first bump map 102 is indicative of a first set of positions of bumps. In some embodiments, the first set of positions corresponds to positions of at least one of connection elements, interconnect structures, contacts, vias, metal lines, etc. on a wafer. In some embodiments, the first bump map 102 comprises one or more coordinates indicative of a position of a bump. In some embodiments, the one or more coordinates comprise an x-coordinate along an x-axis (shown in FIG. 1A) and a z-coordinate along a z-axis (shown in FIG. 1A). In some embodiments, the first bump map 102 is indicative of a first set of sizes of the bumps. Embodiments are contemplated in which the first bump map 102 is indicative of the first set of positions and is not indicative of the first set of sizes. In some embodiments, the first set of sizes are the same, such as where the first bump map 102 indicates that all of the bumps have a first size, such as a first critical dimension. In some embodiments, the first bump map 102 comprises a critical dimension indicative of a size of the first set of sizes, such as the first size. In some embodiments, the size comprises a lateral size, such as at least one of a width, a length, a dimension, etc. of a bump.

In some embodiments, regions of the plurality of regions are defined by a grid 110 on the first bump map 102. In FIG. 1A, a bottom row of the grid 110 defines regions 104a, 104b, 104c, 104d, and 104e of the plurality of regions. In some embodiments, the first plurality of bump densities 108 comprises bump densities associated with some and/or all regions of the plurality of regions. In some embodiments, the first plurality of bump densities 108 is determined using a bump density determination module 112. In FIG. 1A, the first plurality of bump densities 108 is illustrated as a matrix, where a bottom row of the matrix comprises bump densities 106a, 106b, 106c, 106d, and 106e associated with the regions 104a, 104b, 104c, 104d, and 104e, respectively.

FIG. 1B illustrates shapes of bumps of the first bump map 102, according to some embodiments. In some embodiments, a bump of the first bump map 102 has an octagonal shape 122. In some embodiments, the bump that has the octagonal shape 122 is a Chip-on-Wafer-on-Substrate (CoWoS) micro-bump. In some embodiments, the first bump map 102 comprises a critical dimension (indicative of a size of the bump) corresponding to a medium diagonal 118 of the bump. In some embodiments, the medium diagonal 118 is between about 10 micrometers to about 30 micrometers, such as about 18 micrometers. Other values of the medium diagonal 118 are within the scope of the present disclosure.

In some embodiments, a bump of the first bump map 102 has a circular shape 124. In some embodiments, the bump that has the circular shape 124 is a flip chip bump, such as a flip chip copper bump or other type of flip chip bump. In some embodiments, the bump that has the circular shape 124 is a controlled collapse chip connection (C4) bump. In some embodiments, the first bump map 102 comprises a critical dimension (indicative of a size of the bump) corresponding to a diameter 120 of the bump. In some embodiments, the diameter 120 is between about 50 micrometers to about 110 micrometers, such as about 80 micrometers. Other values of the diameter 120 are within the scope of the present disclosure.

Other shapes of bumps of the first bump map 102 other than those shown in FIG. 1B are within the scope of the present disclosure.

In some embodiments, the bump density 106a (shown in FIG. 1A) associated with the region 104a is based upon a total area of the region 104a and an area, of the region 104a, occupied by one or more bumps in the region 104a. In some embodiments, the bump density 106a is equal to the area occupied by the one or more bumps divided by the total area, such as where the bump density 106a corresponds to a proportion, of the region 104a, that is occupied by one or more bumps in the region 104a. In FIG. 1A, the bump density 106a being 5 indicates that 5% of the region 104a is occupied by bumps. In some embodiments, the area occupied by the one or more bumps is determined based upon a sum of one or more areas of the one or more bumps. In some embodiments, the one or more areas of the one or more bumps are determined based upon one or more sizes, of the one or more bumps, indicated by the first bump map 102. In an embodiment in which each bump of the first bump map 102 is the same size, the one or more areas of the one or more bumps are each the same area. In some embodiments, the bump density 106a is

$$ρ = \frac{1}{{L}^{2}} {\sum }_{i = 1}^{N} {A}_{i} ,$$

where L (shown in FIG. 1A) corresponds to a length of a side of the region 104a, L² corresponds to a total area of the region 104a in an embodiment in which the region 104a is a square-shaped window of the first bump map 102, N corresponds to a quantity of bumps in the region 104a, and Aᵢ corresponds to an area of a bump in the region 104a. In some embodiments, each region of one, some and/or all regions of the plurality regions have the same dimensions, such as where each region of one, some and/or all regions are square-shaped windows with sides having lengths equal to L. In some embodiments, the area of the bump is Aᵢ=k·CD², where CD is a critical dimension (indicative of size) of the bump, and where k depends upon a shape of the bump. In some embodiments, if the bump has an octagonal shape 122 (where CD corresponds to a medium diagonal of the octagonal shape 122), k=(2\sqrt{2}−2). In some embodiments, if the bump has a circular shape 124 (where CD corresponds to a diameter of the circular shape 124),

$$k = ( \frac{π}{4} ) .$$

In some embodiments, the bump density 106a associated with the region 104a is based upon a quantity of bumps in the region 104a. In some embodiments, the bump density 106a is equal to the quantity of bumps in the region 104a, such as where a bump density of the first plurality of bump densities 108 corresponds to a quantity of bumps per region.

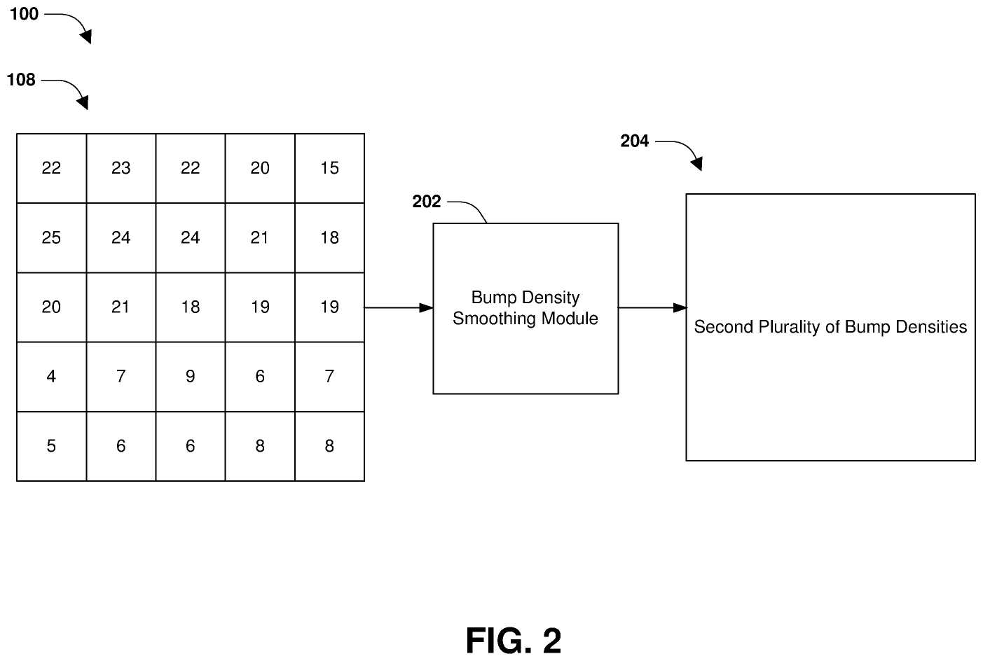

With respect to FIG. 2, a second plurality of bump densities 204 associated with the plurality of regions of the first bump map 102 is determined. In some embodiments, the first plurality of bump densities 108 is smoothed, such as by a bump density smoothing module 202, to determine the second plurality of bump densities 204 associated with the plurality of regions. In some embodiments, the bump density smoothing module 202 comprises a smoothing filter, such as a Gaussian filter, that is used to smooth the first plurality of bump densities 108 to determine the second plurality of bump densities 204. In some embodiments, the bump density smoothing module 202 performs convolution-based smoothing on the first plurality of bump densities 108 to determine the second plurality of bump densities 204.

A bump density of the second plurality of bump densities 204 is determined based upon one or more bump densities of the first plurality of bump densities 108. In some embodiments, a bump density, of the second plurality of bump densities 204, associated with a region of the first bump map 102 is determined based upon a set of bump densities, of the first plurality of bump densities 108, comprising a bump density associated with the region.

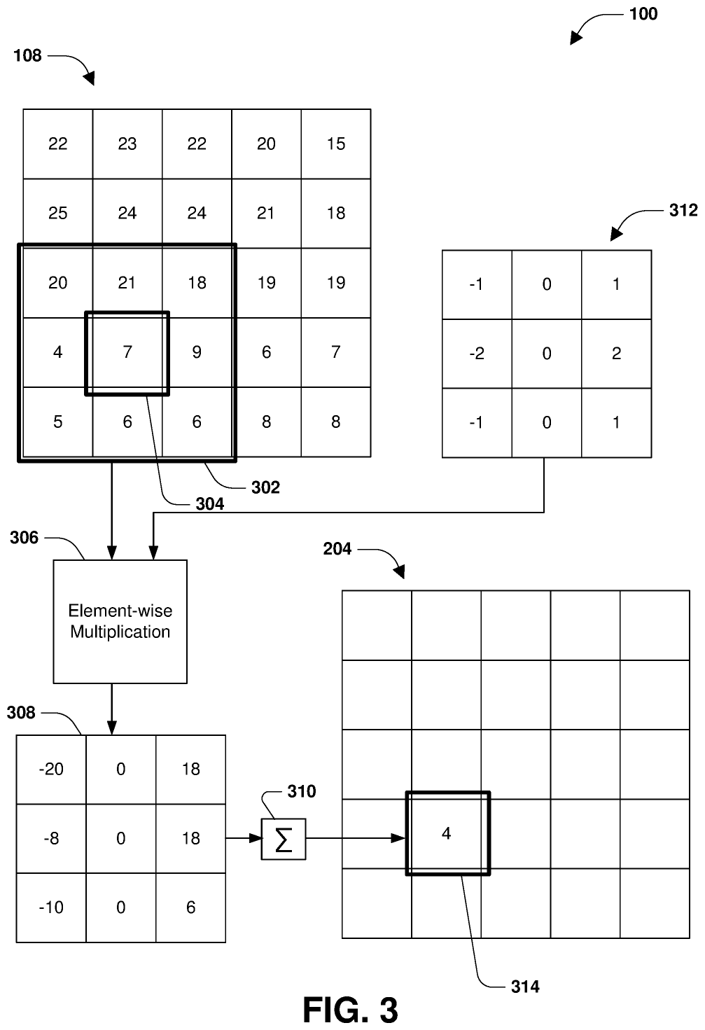

FIG. 3 illustrates determination of a bump density of the second plurality of bump densities 204. The first plurality of bump densities 108 comprises a first bump density 304 associated with a region 104f (shown in FIG. 1A) of the first bump map 102. The second plurality of bump densities 204 comprises a second bump density 314 associated with the region 104f of the first bump map 102. A set of bump densities 302, of the first plurality of bump densities 108, is identified. The set of bump densities 302 comprises the first bump density 304 and one or more bump densities of the first plurality of bump densities 108. In some embodiments, the one or more bump densities comprise bump densities associated with regions, of the plurality of regions of the first bump map 102, that at least one of are adjacent with, in contact with, surround, etc. the region 104f. In some embodiments, the second bump density 314 is determined based upon the set of bump densities 302. In some embodiments, bump densities of the set of bump densities 302 are combined to determine the second bump density 314, of the second plurality of bump densities 204, associated with the region 104f. In FIG. 3, the set of bump densities 302 is multiplied 306 (via element-wise multiplication) with a first matrix 312 to determine a second matrix 308. In some embodiments, the first matrix 312 corresponds to a kernel, such as a convolution matrix, of the bump density smoothing module 202. In some embodiments, the second matrix 308 corresponds to a Hadamard product of the set of bump densities 302 and the first matrix 312. In some embodiments, values of the second matrix 308 are summed 310 to determine the second bump density 314, of the second plurality of bump densities 204, associated with the region 104f. Embodiments are contemplated in which the second bump density 314 and/or the second plurality of bump densities 204 are determined using other techniques. In some embodiments, other bump densities of the second plurality of bump densities 204 other than the second bump density 314 are determined using one or more of the techniques provided herein with respect to determining the second bump density 314.

In some embodiments, a uniformity of bump densities of the second plurality of bump densities 204 is higher than a uniformity of bump densities of the first plurality of bump densities 108, such as due, at least in part, to smoothing the first plurality of bump densities 108 to determine the second plurality of bump densities 204. In some embodiments, a variance of the second plurality of bump densities 204 is smaller than a variance of the first plurality of bump densities 108, such as due, at least in part, to smoothing the first plurality of bump densities 108 to determine the second plurality of bump densities 204.

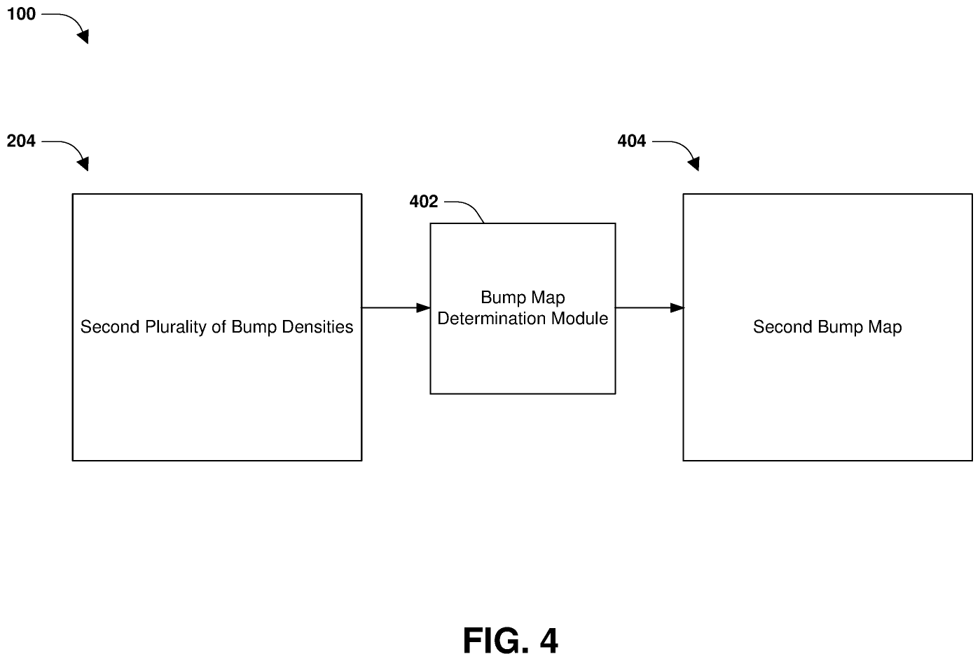

With respect to FIG. 4, a second bump map 404 is determined based upon the second plurality of bump densities 204 and the first bump map 102 that is indicative of at least one of the first set of sizes or the first set of positions. In some embodiments, the second bump map 404 is determined using a bump map determination module 402. In some embodiments, the second bump map 404 is indicative of a second set of sizes of bumps. In some embodiments, such as where the first bump map 102 is indicative of the first set of sizes of the bumps, each size of one, some and/or all sizes of the first set of sizes is modified, based upon the second plurality of bump densities 204, to determine the second set of sizes of bumps. In some embodiments, the second bump map 404 is indicative of the first set of positions of bumps, such as where positions of bumps indicated by the first bump map 102 are not changed in the second bump map 404.

In some embodiments, the first bump map 102 is indicative of a second size of a first bump of the bumps indicated by the first bump map 102. In some embodiments, the second bump map 404 is indicative of a third size, of the first bump, different than the second size. In some embodiments, the first bump map 102 comprises a first critical dimension indicative of the second size. In some embodiments, the second bump map 404 comprises a second critical dimension indicative of the third size. In some embodiments, the second size of the first bump is modified, based upon the second plurality of bump densities 204, to the third size.

In some embodiments, the second bump map 404 is indicative of one or more fourth sizes of one or more bumps in the region 104f (shown in FIG. 1A) of the first bump map 102. In some embodiments, the one or more fourth sizes are determined based upon the second bump density 314 associated with the region 104f of the first bump map 102. In some embodiments, the second bump density 314 is a target density for the region 104f, such as where the one or more fourth sizes of the one or more bumps in the region 104f are determined such that at least one of a bump density of the region 104f in the second bump map 404 is equal to the second bump density 314 or a difference between the bump density of the region 104f according to the second bump map 404 and the second bump density 314 is smaller than a difference between the first bump density 304 and the second bump density 314.

In some embodiments, the first bump map 102 is indicative of one or more fifth sizes of the one or more bumps in the region 104f. In some embodiments, in a scenario in which the second bump density 314 is larger than the first bump density 304, the one or more fourth sizes of the one or more bumps in the region 104f (as indicated by the second bump map 404) are larger than the one or more fifth sizes of the one or more bumps in the region 104f (as indicated by the first bump map 102) so as to increase a bump density of the region 104f such that at least one of the bump density of the region 104f according to the second bump map 404 is equal to the second bump density 314 or a difference between the bump density of the region 104f according to the second bump map 404 and the second bump density 314 is smaller than a difference between the first bump density 304 and the second bump density 314. In some embodiments, in a scenario in which the second bump density 314 is larger than the first bump density 304, one or more dummy bumps are added to the region 104f so as to increase a bump density of the region 104f such that at least one of the bump density of the region 104f according to the second bump map 404 is equal to the second bump density 314 or a difference between the bump density of the region 104f according to the second bump map 404 and the second bump density 314 is smaller than a difference between the first bump density 304 and the second bump density 314. In some embodiments, the second bump map 404 is indicative of the one or more dummy bumps and the first bump map 102 is not indicative of the one or more dummy bumps. In some embodiments, a dummy bump of the one or more dummy bumps corresponds to a bump that is not used to provide a direct electrical connection between at least one of connection elements, interconnect structures, contacts, vias, metal lines, etc.

In some embodiments, in a scenario in which the second bump density 314 is smaller than the first bump density 304, the one or more fourth sizes of the one or more bumps in the region 104f (as indicated by the second bump map 404) are smaller than the one or more fifth sizes of the one or more bumps in the region 104f (as indicated by the first bump map 102) so as to decrease a bump density of the region 104f such that at least one of the bump density of the region 104f according to the second bump map 404 is equal to the second bump density 314 or a difference between the bump density of the region 104f according to the second bump map 404 and the second bump density 314 is smaller than a difference between the first bump density 304 and the second bump density 314.

In some embodiments, the one or more fourth sizes (indicated by the second bump map 404) comprise a third size of a second bump of the one or more bumps in the region 104f. In some embodiments, the one or more fifth sizes (indicated by the first bump map 102) comprise a fourth size of the second bump of the one or more bumps in the region 104f. In some embodiments, a change in size of the second bump is determined, wherein the change in size is applied to the fourth size of the second bump (as indicated by the first bump map 102) to determine the third size of the second bump (as indicated by the second bump map 404). In some embodiments, the change in size is added to (or subtracted from) the fourth size to determine the third size.

In some embodiments, the change in size is determined based upon at least one of the fourth size, of the second bump, indicated by the first bump map 102, the third size, of the second bump, indicated by the second bump map 404, the second bump density 314 associated with the region 104f in which the second bump is positioned, or a maximum change in size. In some embodiments, the third size of the second bump (indicated by the second bump map 404) is CD_{new}=CD₀+ΔₘₐₓX, where CD₀ is the fourth size of the second bump (indicated by the first bump map 102), A max is a maximum change in size parameter associated with limiting the change in size to be at most the maximum change in size, A max X is the change in size, and/or X is a positive root of the following equation:

$$\frac{k}{{L}^{2}} {\sum }_{i = 1}^{N} ( {Δ}_{max , i}^{2} {X}^{2} ) + \frac{k}{{L}^{2}} {\sum }_{i = 1}^{N} ( 2 {CD}_{0} {Δ}_{max , i} X ) + {ρ}_{0} - {ρ}_{new} = 0 ,$$

where L corresponds to a length of a side of the region 104f in an embodiment in which the region 104f is a square-shaped window of the first bump map 102 and/or the second bump map 404, N corresponds to a quantity of bumps in the region 104f, ρ₀ corresponds to the first bump density 304 (of the first plurality of bump densities 108) associated with the region 104f, Anew corresponds to the second bump density 314 (of the second plurality of bump densities 204) associated with the region 104f, and k depends upon a shape of the second bump. In some embodiments, if the second bump has an octagonal shape 122 (where CD₀ corresponds to a medium diagonal of the octagonal shape 122), k=(2\sqrt{2}−2). In some embodiments, if the second bump has a circular shape 124 (where CD₀ corresponds to a diameter of the circular shape 124),

$$k = ( \frac{π}{4} ) .$$

Other shapes of the second bump, and/or other bumps, other than octagonal and/or circular are within the scope of the present disclosure.

In some embodiments, the first bump map 102 indicates that CD₀ is the same across some and/or all bumps in the region 104f, or that CD₀ is the same across some and/or all bumps in the first bump map 102, such as where each bump of some and/or all bumps in the first bump map 102 has a size corresponding to CD₀. In some embodiments, the change in size is in a range of at least a minimum change in size to at most the maximum change in size. In some embodiments, at least one of the minimum change in size or the maximum change in size are based upon at least one of CD₀ of the second bump, a type of bump of the second bump, a size of bump of the second bump, or a shape of the second bump. In some embodiments, if at least one of the second bump has an octagonal shape 122, the second bump is a CoWoS micro-bump, or CD₀ of the second bump is smaller than a first threshold critical dimension, the minimum change in size is equal to or larger than zero, and the maximum change in size is between about 3 micrometers to about 4 micrometers, such as about 3.5 micrometers. In some embodiments, the first threshold critical dimension is between about 25 micrometers to about 70 micrometers, such as about 40 micrometers. Other values of the first threshold critical dimension are within the scope of the present disclosure. In some embodiments, if at least one of the second bump has a circular shape 124, the second bump is a flip chip bump, the second bump is a C4 bump, or CD₀ of the second bump is larger than the first threshold critical dimension, the minimum change in size is between about −3 micrometers to about −5 micrometers, such as about −4 micrometers, and the maximum change in size is between about 3 micrometers to about 5 micrometers, such as about 4 micrometers. Other values of the minimum change in size and/or the maximum change in size are within the scope of the present disclosure.

In some embodiments, other sizes of the one or more fourth sizes other than the third size are determined using one or more of the techniques provided herein with respect to determining the third size of the second bump. In some embodiments, the one or more fourth sizes are set to the same size, such CD_{new} In some embodiments, other sizes of the second set of sizes (indicated by the second bump map 404) other than the one or more fourth sizes are determined using one or more of the techniques provided herein with respect to determining the third size of the second bump and/or determining the one or more fourth sizes of the one or more bumps in the region 104f.

In some embodiments, by determining bump sizes of the second bump map 404 based upon the second plurality of bump densities 204, bump densities across the plurality of regions according to the second bump map 404 have at least one of increased uniformity, reduced variance, etc. as compared to bump densities across the plurality of regions according to the first bump map 102.

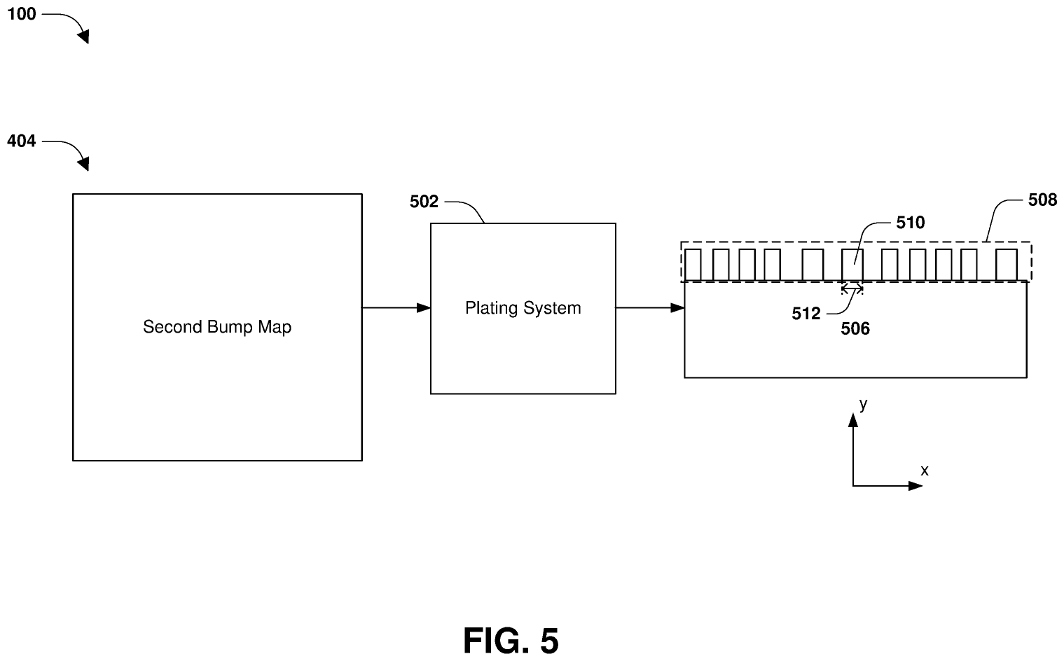

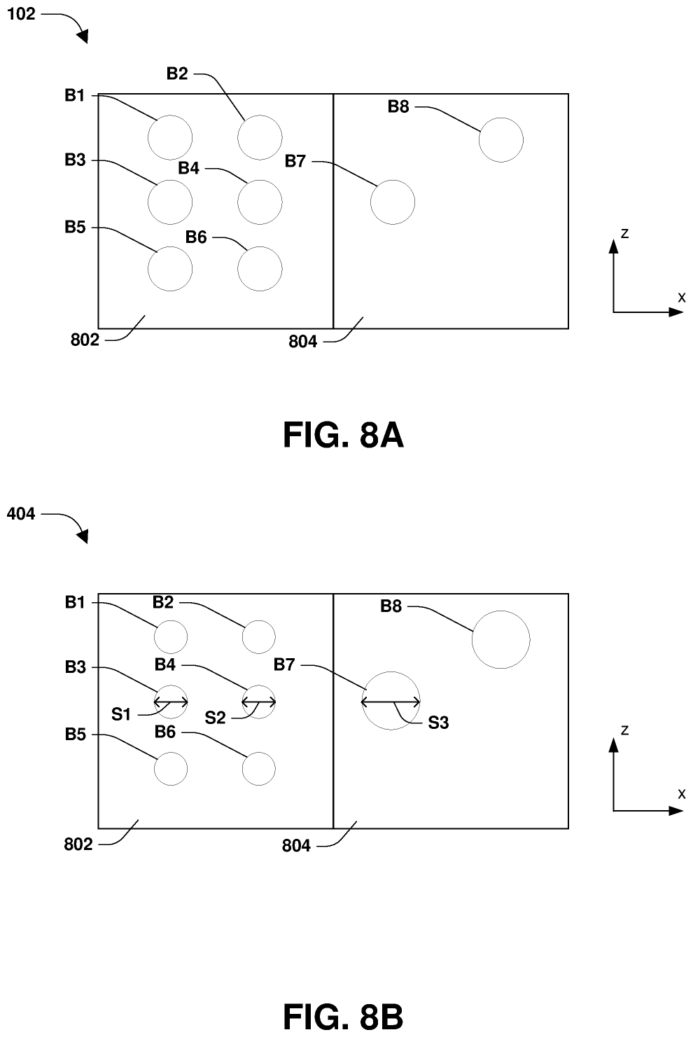

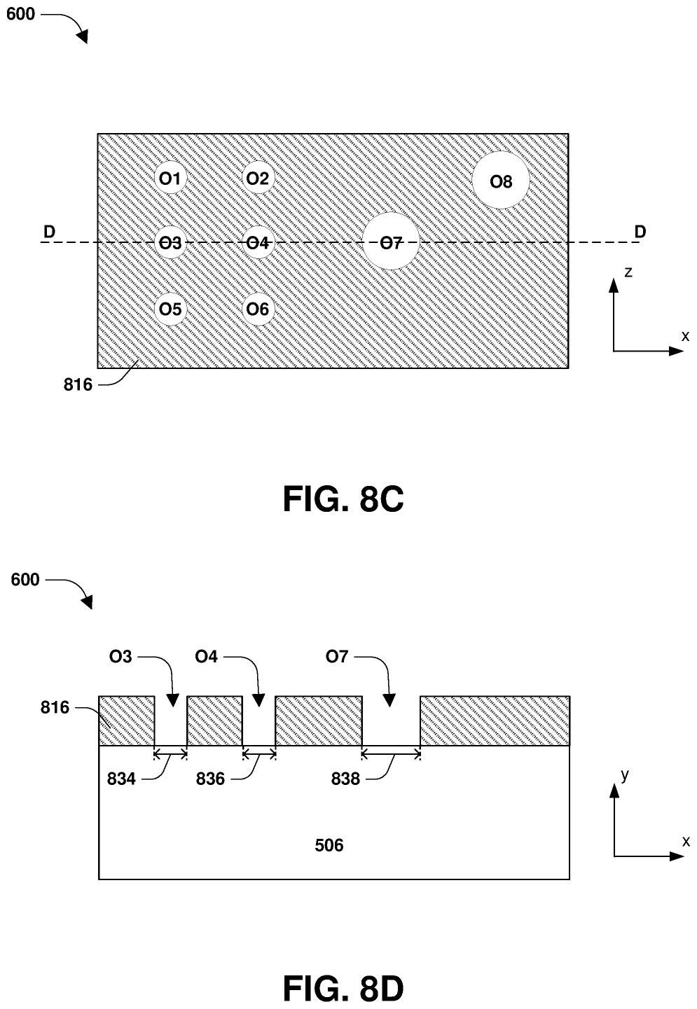

FIG. 5 illustrates the second bump map 404 being used to form a bump array 508 on a wafer 506. In some embodiments, the bump array 508 is formed, according to the second bump map 404, by a plating system 502. In some embodiments, lateral positions and lateral sizes of bumps of the bump array 508 are based upon the second bump map 404. A lateral position and a lateral size 512 of a bump 510 of the bump array 508 is based upon a position and a size of the bump, respectively, indicated by the second bump map 404. In some embodiments, the lateral position of the bump 510 of the bump array 508 corresponds to a position, along the x-axis (shown in FIG. 5) and the z-axis (shown in FIGS. 8A-8C), on a top surface of the wafer 506. The z-axis is perpendicular to the x-axis and a y-axis (vertical axis shown in FIG. 5). In some embodiments, the lateral size 512 of the bump 510 corresponds to a critical dimension of the bump 510, such as at least one of a width of the bump 510, a length of the bump 510, a diameter of the bump 510, a medium diagonal of the bump 510, etc.

In some embodiments, the wafer 506 comprises at least one of a substrate, a die, etc. In some embodiments, at least one of connection elements, interconnect structures, contacts, vias, metal lines, etc. are disposed on the wafer 506, such as on the top surface of the wafer 506. In some embodiments, the bump array 508 is formed over the wafer 506. In some embodiments, bumps of the bump array 508 are in contact with at least one of the connection elements, the interconnect structures, the contacts, the vias, the metal lines, etc. In some embodiments, the bump array 508 is used to connect at least one of the connection elements, the interconnect structures, the contacts, the vias, the metal lines, etc. to a device comprising at least one of a second wafer, circuitry, etc.

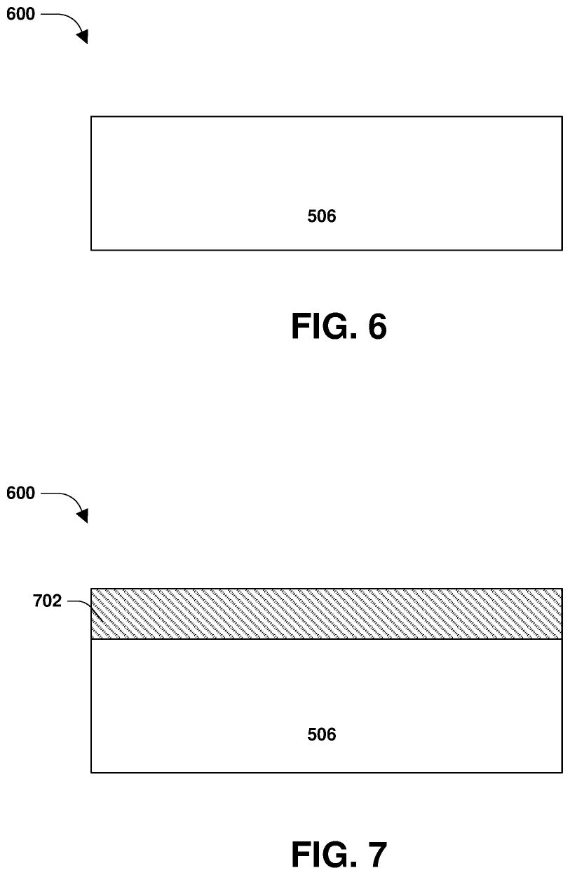

FIGS. 6-9 illustrate a semiconductor device 600 at various stages of fabrication, in accordance with some embodiments. FIGS. 6, 7, and 9 illustrate cross-sectional views of the semiconductor device 600. FIG. 8C illustrates a top view of the semiconductor device 600. FIG. 8D illustrates a cross-sectional view of the semiconductor device 600 taken along line D-D of FIG. 8C. FIG. 6 illustrates the wafer 506, according to some embodiments. FIG. 7 illustrates a photoresist 702 formed over the wafer 506, according to some embodiments. The photoresist 702 at least one of overlies the wafer 506, is in direct contact with the top surface of the wafer 506, or is in indirect contact with the top surface of the wafer 506. The photoresist 702 is formed by at least one of physical vapor deposition (PVD), sputtering, chemical vapor deposition (CVD), low pressure CVD (LPCVD), atomic layer chemical vapor deposition (ALCVD), ultrahigh vacuum CVD (UHVCVD), reduced pressure CVD (RPCVD), atomic layer deposition (ALD), molecular beam epitaxy (MBE), liquid phase epitaxy (LPE), spin on, growth, or other suitable techniques.

The photoresist 702 comprises a light-sensitive material, where properties, such as solubility, of the photoresist 702 are affected by light. The photoresist 702 is a negative photoresist or a positive photoresist. With respect to a negative photoresist, regions of the negative photoresist become insoluble when illuminated by a light source, such that application of a solvent to the negative photoresist during a subsequent development stage removes non-illuminated regions of the negative photoresist. A pattern formed in the negative photoresist is thus a negative of a pattern defined by opaque regions of a template, such as a mask, between the light source and the negative photoresist. In a positive photoresist, illuminated regions of the positive photoresist become soluble and are removed via application of a solvent during development. Thus, a pattern formed in the positive photoresist is a positive image of opaque regions of the template, such as a mask, between the light source and the positive photoresist.

FIG. 8A illustrates at least a portion of the first bump map 102, according to some embodiments. FIG. 8B illustrates at least a portion of the second bump map 404, according to some embodiments. In FIGS. 8A and 8B, bumps of the first bump map 102 and the second bump map 404 have a circular shape 124. Other shapes of the bumps are within the scope of the present disclosure. With respect to FIG. 8A, the first bump map 102 is indicative of six bumps in a first region 802 of the plurality of regions and two bumps in a second region 804 of the plurality of regions, wherein sizes of the bumps in the first region 802 and the second region 804 are the same (e.g., the sizes of the bumps in the first region 802 and the second region 804 correspond to CD₀). Accordingly, according to the first bump map 102, a bump density of the first region 802 is about 3 times higher than a bump density of the second region 804. With respect to FIG. 8B, in the second bump map 404, sizes of the six bumps in the first region 802 are reduced and sizes of the two bumps in the second region 804 are increased, such as due, at least in part, to smoothing the first plurality of bump densities 108 to determine the second plurality of bump densities 204 and determining the second bump map 404 based upon the second plurality of bump densities 204. Accordingly, in the second bump map 404, a bump density of the first region 802 is reduced and a bump density of the second region 804 is increased. In some embodiments, compared with the first bump map 102, in the second bump map 404, a difference between the bump density of the first region 802 and the bump density of the second region 804 is smaller. The smaller difference between the bump density of the first region 802 and the bump density of the second region 804 results in reduced bump height variation between bumps, of the bump array 508, corresponding to the first region 802 and bumps, of the bump array 508, corresponding to the second region 804, thereby increasing a uniformity of bump heights of the bump array 508.

FIGS. 8C and 8D illustrate a patterned photoresist 816 formed from the photoresist 702, according to some embodiments. In some embodiments, the patterned photoresist 816 is formed based upon the second bump map 404. In some embodiments, the template, used to pattern the photoresist 702 to form the patterned photoresist 816, is formed based upon the second bump map 404. The patterned photoresist 816 defines openings exposing portions of the wafer 506. In some embodiments, the openings comprise an opening O1 (shown in FIG. 8C) corresponding to a bump B1 (shown in FIG. 8B) in the second bump map 404, an opening O2 (shown in FIG. 8C) corresponding to a bump B2 (shown in FIG. 8B) in the second bump map 404, an opening O3 (shown in FIGS. 8C and 8D) corresponding to a bump B3 (shown in FIG. 8B) in the second bump map 404, an opening O4 (shown in FIGS. 8C and 8D) corresponding to a bump B4 (shown in FIG. 8B) in the second bump map 404, an opening O5 (shown in FIG. 8C) corresponding to a bump B5 (shown in FIG. 8B) in the second bump map 404, an opening O6 (shown in FIG. 8C) corresponding to a bump B6 (shown in FIG. 8B) in the second bump map 404, an opening O7 (shown in FIGS. 8C and 8D) corresponding to a bump B7 (shown in FIG. 8B) in the second bump map 404, and an opening O8 (shown in FIG. 8C) corresponding to a bump B8 (shown in FIG. 8B) in the second bump map 404. In some embodiments, a size 834 (shown in FIG. 8D) of the opening O3 corresponds to a size S1 (shown in FIG. 8B), of the bump B3, indicated by the second bump map 404, a size 836 (shown in FIG. 8D) of the opening O4 corresponds to a size S2 (shown in FIG. 8B), of the bump B4, indicated by the second bump map 404, and a size 838 of the opening O7 corresponds to a size S3 (shown in FIG. 8B), of the bump B7, indicated by the second bump map 404.

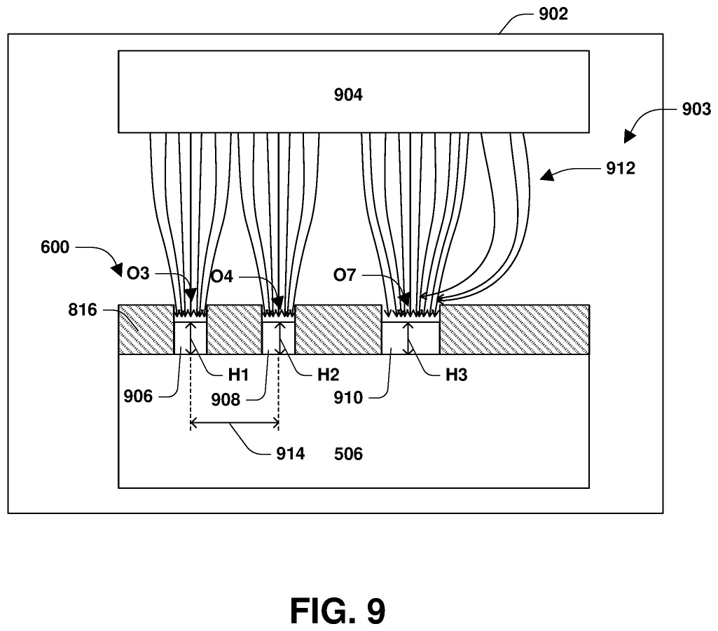

FIG. 9 illustrates a plating process performed to form bumps of the bump array 508. In some embodiments, the plating process is performed when the patterned photoresist 816 is disposed on the wafer 506. The plating process is performed in an electroplating chamber 902, of the plating system 502, defining a plating area 903 in which the wafer 506 is plated to form the bump array 508. In some embodiments, during the plating process, anode material is transferred from an anode 904 to the wafer 506, wherein the anode material accumulates in openings defined in the patterned photoresist 816 to form bumps of the bump array 508. In some embodiments, a power source (not shown) is electrically coupled to the anode 904 and a cathode, such as the wafer 506. The power source is configured to pass current, such as direct current, through plating solution in the electroplating chamber 902 such that the anode 904 loses electrons and the wafer 506 becomes negatively charged. Electric field lines 912 associated with the current is shown in FIG. 9. Loss of electrons at the anode 904 causes some of the anode material of the anode 904 to at least one of dissolve into the plating solution or be converted into ions, such as positively charged metal ions. The ions from the anode 904 flow through the plating area 903, such as through and/or with the plating solution, to the wafer 506. The ions are at least one of neutralized, reduced, or deposited onto the wafer 506, such as deposited onto exposed portions of the top surface of the wafer 506. The anode 904 and the anode material comprise at least one of copper, nickel, tin, or other suitable material. In some embodiments, the patterned photoresist 816 is removed after the bump array 508 is formed on the wafer 506. In some embodiments, the patterned photoresist 816 is removed by at least one of an etching process, chemical mechanical planarization (CMP), a washing process, or other suitable techniques. In some embodiments, the etching process is at least one of a dry etching process, a wet etching process, an anisotropic etching process, an isotropic etching process or another suitable etching process. The etching process uses at least one of fluorine, hydrogen fluoride (HF), diluted HF, sulfur hexafluoride (SF₆), a chlorine compound such as hydrogen chloride (HCl₂), hydrogen sulfide (H₂S), tetrafluoromethane (CFO, or other suitable material. Other processes and techniques for removing the patterned photoresist 816 are within the scope of the present disclosure.

In some embodiments, as compared to using a patterned photoresist formed based upon the first bump map 102 to form the bump array 508, forming the bump array 508 using the patterned photoresist 816 that is formed based upon the second bump map 404 provides for reduced variation in rates of accumulation of the anode material across openings in the patterned photoresist 816, thereby providing for increased uniformity of bump heights of the bump array 508 formed from the anode material. In some embodiments, the reduced variation in rates of accumulation is due, at least in part, to an increased uniformity of current intensity across openings in the patterned photoresist 816, such as due, at least in part, to the reduced variations of bump densities across the plurality of regions of the second bump map 404 in comparison with the first bump map 102. In some embodiments, anode material from the anode 904 accumulates in at least one of the opening O3 to form a bump 906 of the bump array 508, the opening O4 to form a bump 908 of the bump array 508, or the opening O7 to form a bump 910 of the bump array 508. The bumps 906, 908, and 910 correspond to the bumps B3, B4, and B7 (shown in FIGS. 8A and 8B), respectively. In some embodiments, due to the reduced variation in rates of accumulation of the anode material across openings in the patterned photoresist 816, variations between heights H1, H2 and H3 of bumps 906, 908, and 910, respectively, are reduced, thereby improving a coplanarity of the bumps 906, 908 and 910 as compared to an implementation in which the bump array 508 is formed based upon the first bump map 102. FIG. 9 illustrates a bump pitch 914 according to some embodiments. In some embodiments, the bump pitch 914 comprises a distance between a center of the bump 906 and a center of the bump 908.

Since the first bump map 102 (at least a portion of which is shown in FIG. 8A) provides for the bump density of the first region 802 being larger than the bump density of the second region 804, in a bump array formed based upon the first bump map 102, first heights of bumps corresponding to the bumps B3 and B4 are smaller than a second height of a bump corresponding to the bump B7. In some embodiments, in the bump array 508 formed based upon the second bump map 404, the heights H1 and H2 of the bumps 906 and 908 corresponding to the bumps B3 and B4 are larger than the first heights, such as due, at least in part, to reducing sizes of the bumps B3 and B4 in the second bump map 404 as compared to the first bump map 102, and thereby reducing the sizes 834 and 836 of the openings O3 and O4 in which anode material accumulates to form the bumps 906 and 908. In some embodiments, in the bump array 508 formed based upon the second bump map 404, the height H3 of the bump 910 corresponding to the bump B7 is smaller than the second height, such as due, at least in part, to increasing a size of the bump B7 in the second bump map 404 as compared to the first bump map 102, and thereby increasing the size 838 of the opening O7 in which anode material accumulates to form the bump 910. In some embodiments, increasing the heights H1 and H2 of the bumps 906 and 908 as compared to the first heights and reducing the height H3 of the bump 910 as compared to the second height provides for at least one of a smaller difference between the height H1 of the bump 906 and the height H3 of the bump 910 or a smaller difference between the height H2 of the bump 908 and the height H3 of the bump 910.

In some embodiments, the bump array 508 is used to connect at least one of the connection elements, the interconnect structures, the contacts, the vias, the metal lines, etc. to a device comprising at least one of a second wafer, circuitry, etc. In some embodiments, bumps of the bump array 508 are soldered to the device, such as to a second bump array on the device. Variations in bump heights of the bump array 508 can cause bumps of the bump array 508 to be disconnected from the device, such as due, at least in part, to a taller bump of the bump array 508 preventing a shorter bump of the bump array 508 from reaching or connecting to a component that the shorter bump is supposed to connect to. In some embodiments, the increased uniformity of bump heights of the bump array 508 provides for improved connection between the semiconductor device 600 and the device, where taller bumps do not prevent shorter bumps from connecting to components of the device. Thus, the increased uniformity of bump heights of the bump array 508 provides for improved operation and performance of at least one of the semiconductor device 600 or the device to which the semiconductor device 600 is connected via the bump array 508. In some embodiments, the increased uniformity of bump heights of the bump array 508 provides for improved yield of at least one of the bump array 508 or one or more instances of the semiconductor device 600.

Without using techniques of the present disclosure, generating a bump map that provides for at least one of sufficient bump height uniformity of a resulting bump array or sufficient connectivity between the resulting bump array and a device requires significant manual effort, trial and error, etc. However, in accordance with some embodiments provided herein, based upon the first bump map 102 indicative of the first set of positions of bumps, the second bump map 404 is automatically determined with configured bump sizes, such as updated lateral sizes corresponding to critical dimensions of bumps, that provide for formation of a bump array with improved height uniformity and improved connectivity between the bump array and a device. Accordingly, the second bump map 404 may be generated more quickly, with less manual effort, reduced cost, etc. and/or bump arrays may be formed according to the second bump map 404 with reduced production cost. In some embodiments, by forming the bump array using the techniques herein, lateral sizes of bumps across the bump array are larger in regions with larger pitches between bumps and smaller in regions with smaller pitches between bumps, whereas in other implementations, lateral sizes of bumps are constant throughout a bump array regardless of changes in pitches between bumps.

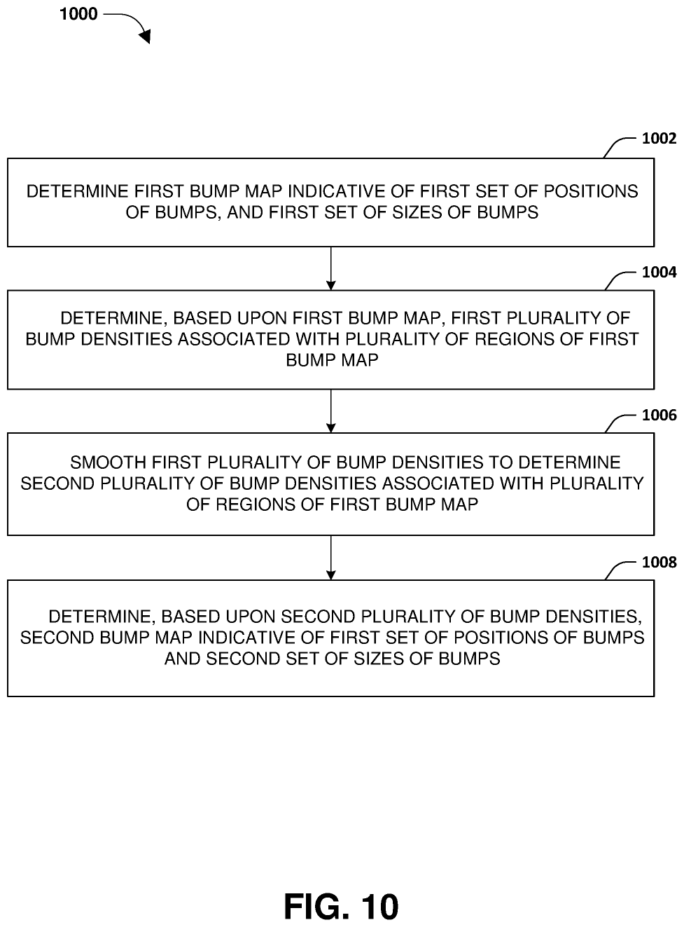

A method 1000 is illustrated in FIG. 10, in accordance with some embodiments. At 1002, a first bump map indicative of a first set of positions of bumps and a first set of sizes of the bumps is determined. At 1004, based upon the first bump map, a first plurality of bump densities associated with a plurality of regions of the first bump map is determined. At 1006, the first plurality of bump densities is smoothed to determine a second plurality of bump densities associated with the plurality of regions of the first bump map. At 1008, based upon the second plurality of bump densities, a second bump map indicative of the first set of positions of the bumps and a second set of sizes of the bumps is determined.

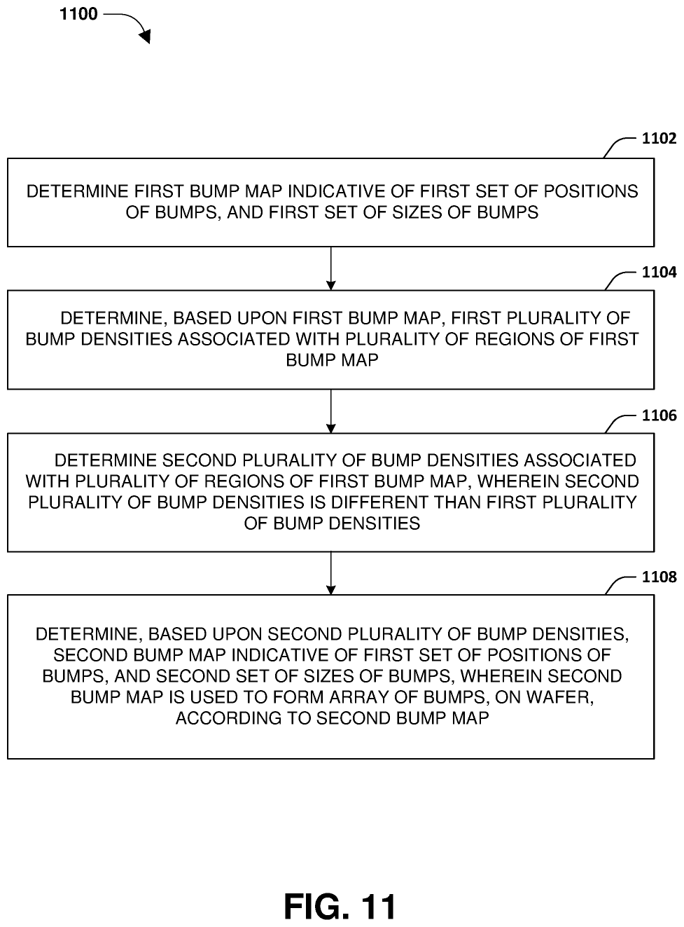

A method 1100 is illustrated in FIG. 11, in accordance with some embodiments. At 1102, a first bump map indicative of a first set of positions of bumps and a first set of sizes of the bumps is determined. At 1104, based upon the first bump map, a first plurality of bump densities associated with a plurality of regions of the first bump map is determined. At 1106, a second plurality of bump densities associated with the plurality of regions of the first bump map is determined. The second plurality of bump densities is different than the first plurality of bump densities. At 1108, based upon the second plurality of bump densities, a second bump map indicative of the first set of positions of the bumps and a second set of sizes of the bumps is determined. The second bump map is used to form a bump array, on a wafer, according to the second bump map.

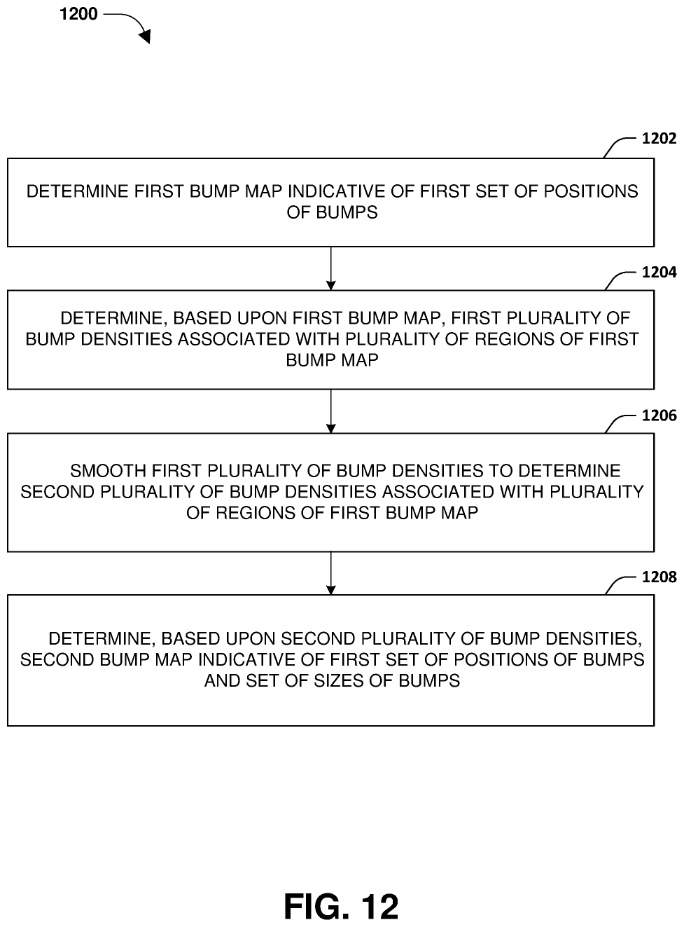

A method 1200 is illustrated in FIG. 12, in accordance with some embodiments. At 1202, a first bump map indicative of a first set of positions of bumps is determined. At 1204, based upon the first bump map, a first plurality of bump densities associated with a plurality of regions of the first bump map is determined. At 1206, the first plurality of bump densities is smoothed to determine a second plurality of bump densities associated with the plurality of regions of the first bump map. At 1208, based upon the second plurality of bump densities, a second bump map indicative of the first set of positions of the bumps and a set of sizes of the bumps is determined.

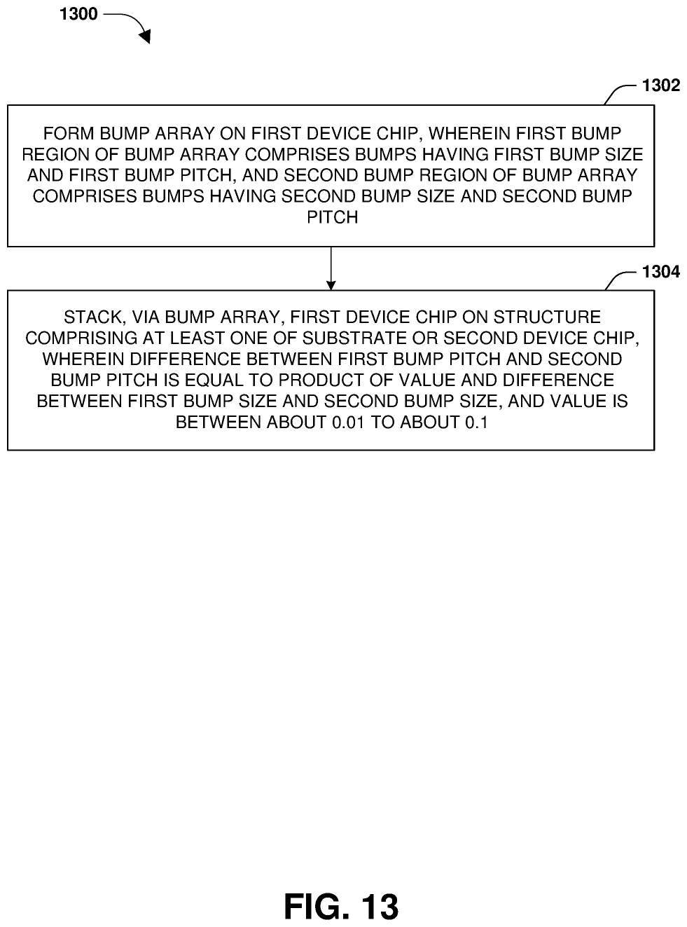

A method 1300 of forming a semiconductor device is illustrated in FIG. 13, in accordance with some embodiments. At 1302, a bump array is formed on a first device chip. In some embodiments, the bump array is formed using a bump map determined using one or more of the techniques provided herein. A first bump region of the bump array comprises bumps having a first bump size and a first bump pitch. A second bump region of the bump array comprises bumps having a second bump size and a second bump pitch. At 1304, the first device chip is stacked on a structure via the bump array. The structure comprises at least one of a substrate or a second device chip. A difference between the first bump pitch and the second bump pitch is equal to a product of a value and a difference between the first bump size and the second bump size. |P2−P1|=k(|L2−L1|), wherein P1 is the first bump pitch, P2 is the second bump pitch, L1 is the first bump size, L2 is the second bump size, and k is the value. The value is between about 0.01 to about 0.1.

In some embodiments, bumps of the bump array are soldered to bumps of a second bump array on the structure to stack the first device chip on the structure.

In some embodiments, forming the bump array comprises performing a plating process, such as an electroplating process. In some embodiments, the is based upon the plating process and at least one of a first bump density of the first bump region or a second bump density of the second bump region.

In some embodiments, the first device chip comprises at least one of a logic chip or a memory chip.

In some embodiments, the first device chip comprises a logic chip and the second device chip comprises a memory chip.

In some embodiments, a bump of the bump array comprises at least one of copper, nickel, or tin.

In some embodiments, the bump array comprises at least one of a flip chip bump, a CoWoS micro-bump, or a C4 bump.

In some embodiments, a first bump density of the first bump region is larger than a second bump density of the second bump region. In some embodiments, the first bump density is smaller than a product of the second bump density and 1.15.

In some embodiments, the first bump size comprises a first lateral size, such as at least one of a width, a length, a dimension, etc., of a bump in the first bump region.

In some embodiments, the second bump size comprises a second lateral size, such as at least one of a width, a length, a dimension, etc., of a bump in the second bump region.

In some embodiments, the first bump pitch comprises a first distance between two bumps in the first bump region, such as a distance between a center of a first bump of the two bumps and a center of a second bump of the two bumps.

In some embodiments, the second bump pitch comprises a second distance between two bumps in the second bump region, such as a distance between a center of a third bump of the two bumps and a center of a fourth bump of the two bumps.

In some embodiments, a height of a bump of the bump array is between about 45 micrometers to about 65 micrometers, such as between about 49.5 micrometers to about 60.5 micrometers. In some embodiments, each bump of one, some or all bumps of the bump array has a height that is between about 45 micrometers to about 65 micrometers, such as between about 49.5 micrometers to about 60.5 micrometers.

In some embodiments, a bump coplanarity of the bump array is less than about 30 micrometers, such as less than or equal to about 20 micrometers, so that a difference in heights, for example, between different bumps is less than or no more than about 20 micrometers. For example, if a first bump has a height of 50 micrometers then a second bump would have a height that is less than 80 micrometers or greater than 20 micrometers so that a difference between the heights of the first bump and the second bump is less than or no greater than 30 micrometers. In some embodiments, the bump coplanarity of the bump array being less than about 30 micrometers, such as less than about 20 micrometers, may provide for at least one of improved bond performance or improved yield associated with the bump array.

In some embodiments, bump sizes of bump regions of the bump array are linearly proportional to bump pitches of the bump regions. In some embodiments, for each bump region of one, some and/or all bump regions of the bump array, P=C×L, where C corresponds to a constant, P corresponds to a bump pitch of bumps of the bump region, and L corresponds to a bump size of bumps of the bump region.

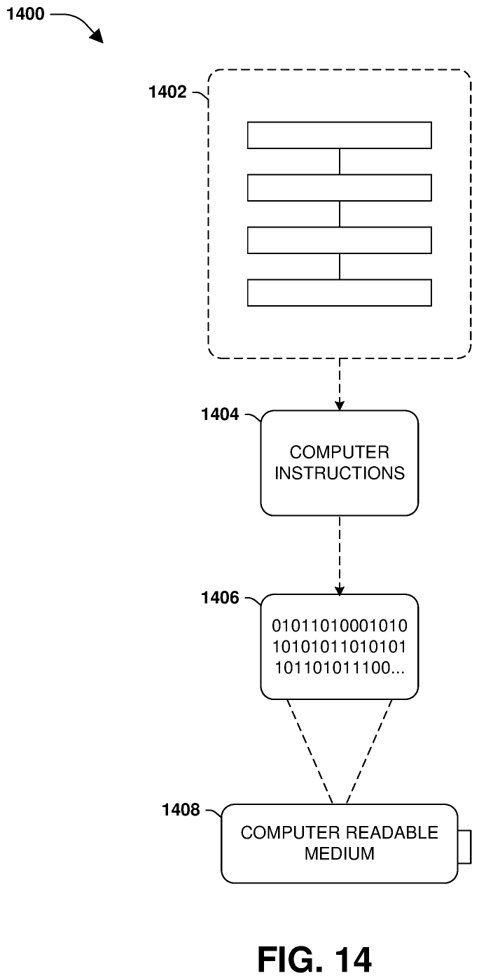

One or more embodiments involve a computer-readable medium comprising processor-executable instructions configured to implement one or more of the techniques presented herein. An exemplary computer-readable medium is illustrated in FIG. 14, wherein the embodiment 1400 comprises a computer-readable medium 1408 (e.g., a CD-R, DVD-R, flash drive, a platter of a hard disk drive, etc.), on which is encoded computer-readable data 1406. This computer-readable data 1406 in turn comprises a set of processor-executable computer instructions 1404 configured to implement one or more of the principles set forth herein when executed by a processor. In some embodiments 1400, the processor-executable computer instructions 1404 are configured to implement a method 1402, such as at least some of the aforementioned method(s) when executed by a processor. In some embodiments, the processor-executable computer instructions 1404 are configured to implement a system, such as at least some of the one or more aforementioned system(s) when executed by a processor. Many such computer-readable media may be devised by those of ordinary skill in the art that are configured to operate in accordance with the techniques presented herein.

In some embodiments, a method is provided. The method includes determining a first bump map indicative of a first set of positions of bumps and a first set of sizes of the bumps. The method includes determining, based upon the first bump map, a first plurality of bump densities associated with a plurality of regions of the first bump map. The method includes smoothing the first plurality of bump densities to determine a second plurality of bump densities associated with the plurality of regions of the first bump map. The method includes determining, based upon the second plurality of bump densities, a second bump map indicative of the first set of positions of the bumps and a second set of sizes of the bumps.

In some embodiments, a method is provided. The method includes determining a first bump map indicative of a first set of positions of bumps and a first set of sizes of the bumps. The method includes determining, based upon the first bump map, a first plurality of bump densities associated with a plurality of regions of the first bump map. The method includes determining a second plurality of bump densities associated with the plurality of regions of the first bump map, wherein the second plurality of bump densities is different than the first plurality of bump densities. The method includes determining, based upon the second plurality of bump densities, a second bump map indicative of the first set of positions of the bumps and a second set of sizes of the bumps. The second bump map is used to form a bump array, on a wafer, according to the second bump map.

In some embodiments, a method is provided. The method includes determining a first bump map indicative of a first set of positions of bumps. The method includes determining, based upon the first bump map, a first plurality of bump densities associated with a plurality of regions of the first bump map. The method includes smoothing the first plurality of bump densities to determine a second plurality of bump densities associated with the plurality of regions of the first bump map. The method includes determining, based upon the second plurality of bump densities, a second bump map indicative of the first set of positions of the bumps and a set of sizes of the bumps.

In some embodiments, a method of forming a semiconductor device is provided. The method includes forming a bump array on a first device chip. A first bump region of the bump array includes bumps having a first bump size and a first bump pitch. A second bump region of the bump array comprises bumps having a second bump size and a second bump pitch. The method includes stacking, via the bump array, the first device chip on a structure comprising at least one of a substrate or a second device chip. A difference between the first bump pitch and the second bump pitch is equal to a product of a value and a difference between the first bump size and the second bump size. The value is between about 0.01 to about 0.1.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A method, comprising:
determining a first bump map indicative of:
a first set of positions of bumps; and
a first set of sizes of the bumps;
determining, based upon the first bump map, a first plurality of bump densities associated with a plurality of regions of the first bump map;
smoothing the first plurality of bump densities to determine a second plurality of bump densities associated with the plurality of regions of the first bump map; and
determining, based upon the second plurality of bump densities, a second bump map indicative of the first set of positions of the bumps and a second set of sizes of the bumps.

2. The method of claim 1, wherein:
the first bump map is indicative of a first size of a first bump of the bumps; and
the second bump map is indicative of a second size, of the first bump, different than the first size.

3. The method of claim 2, wherein:
the first bump map comprises a first critical dimension indicative of the first size; and
the second bump map comprises a second critical dimension indicative of the second size.

4. The method of claim 1, wherein determining the first plurality of bump densities comprises:
determining an area of a portion, of a first region of the plurality of regions, that is occupied by one or more bumps according to the first bump map; and
determining a first bump density associated with the first region based upon the area and a total area of the first region, wherein the first plurality of bump densities comprises the first bump density.

5. The method of claim 4, wherein:
the second plurality of bump densities comprises a second bump density, associated with the first region, different than the first bump density;
determining the second bump map comprises determining, based upon the second bump density, one or more second sizes of the one or more bumps in the first region; and
the second bump map is indicative of the one or more second sizes of the one or more bumps.

6. The method of claim 5, wherein:
determining the one or more second sizes comprises:
determining a change in size of a bump of the one or more bumps based upon:
a first size, of the bump, indicated by the first bump map;
the first bump density; and
the second bump density; and
applying the change in size to the first size to determine a second size, of the one or more second sizes, of the bump.

7. The method of claim 6, wherein:
the change in size is at most a maximum change in size.

8. The method of claim 1, wherein smoothing the first plurality of bump densities to determine the second plurality of bump densities comprises:
identifying a first set of bump densities, of the first plurality of bump densities, comprising:
a first bump density associated with a first region of the plurality of regions; and
one or more second bump densities associated with one or more second regions of the plurality of regions; and
based upon the first set of bump densities, determining a third bump density, associated with the first region, of the second plurality of bump densities.

9. The method of claim 8, wherein:
the third bump density is different than the first bump density.

10. The method of claim 1, wherein:
the second bump map is used to form a bump array on a wafer.

11. The method of claim 10, wherein:
the bump array is formed by a plating system configured to transfer anode material from an anode to the wafer in a plating process to form the bump array.

12. The method of claim 1, wherein:
the second bump map is used to form a patterned photoresist on a wafer; and
the patterned photoresist is used to form a bump array on the wafer.

13. The method of claim 12, wherein:
when the patterned photoresist is disposed on the wafer, the bump array is formed by a plating system configured to transfer anode material from an anode to the wafer in a plating process to form the bump array.

14. A method, comprising:
determining a first bump map indicative of:
a first set of positions of bumps; and
a first set of sizes of the bumps;
determining, based upon the first bump map, a first plurality of bump densities associated with a plurality of regions of the first bump map;
determining a second plurality of bump densities associated with the plurality of regions of the first bump map, wherein the second plurality of bump densities is different than the first plurality of bump densities; and
determining, based upon the second plurality of bump densities, a second bump map indicative of:
the first set of positions of the bumps; and
a second set of sizes of the bumps,
wherein the second bump map is used to form a bump array, on a wafer, according to the second bump map.

15. The method of claim 14, wherein determining the first plurality of bump densities comprises:
determining an area of a portion, of a first region of the plurality of regions, that is occupied by one or more bumps according to the first bump map; and
determining a first bump density associated with the first region based upon the area and a total area of the first region, wherein the first plurality of bump densities comprises the first bump density.

16. The method of claim 15, wherein:
the second plurality of bump densities comprises a second bump density, associated with the first region, different than the first bump density;
determining the second bump map comprises determining, based upon the second bump density, one or more second sizes of the one or more bumps in the first region; and
the second bump map is indicative of the one or more second sizes of the one or more bumps.

17. The method of claim 14, wherein:
the bump array is formed by a plating system configured to transfer anode material from an anode to the wafer in a plating process to form the bump array.

18. A method, comprising:
determining a first bump map indicative of a first set of positions of bumps;
determining, based upon the first bump map, a first plurality of bump densities associated with a plurality of regions of the first bump map;
smoothing the first plurality of bump densities to determine a second plurality of bump densities associated with the plurality of regions of the first bump map; and
determining, based upon the second plurality of bump densities, a second bump map indicative of the first set of positions of the bumps and a set of sizes of the bumps.

19. The method of claim 18, wherein:
determining the first plurality of bump densities comprises:
determining an area of a portion, of a first region of the plurality of regions, that is occupied by one or more bumps according to the first bump map; and
determining a first bump density associated with the first region based upon the area and a total area of the first region, wherein the first plurality of bump densities comprises the first bump density;
the second plurality of bump densities comprises a second bump density, associated with the first region, different than the first bump density;
determining the second bump map comprises determining, based upon the second bump density, one or more second sizes of the one or more bumps in the first region; and
the second bump map is indicative of the one or more second sizes of the one or more bumps.

20. The method of claim 18, wherein:
the second bump map is used to form a bump array on a wafer.

21. A method for forming a semiconductor device, comprising:
forming a bump array on a first device chip, wherein:
a first bump region of the bump array comprises bumps having a first bump size and a first bump pitch; and
a second bump region of the bump array comprises bumps having a second bump size and a second bump pitch; and
stacking, via the bump array, the first device chip on a structure comprising at least one of a substrate or a second device chip, wherein:
a difference between the first bump pitch and the second bump pitch is equal to a product of a value and a difference between the first bump size and the second bump size; and
the value is between about 0.01 to about 0.1.

22. The method of claim 21, wherein:
forming the bump array comprises performing a plating process; and
the value is based upon the plating process and at least one of a first bump density of the first bump region or a second bump density of the second bump region.

23. The method of claim 21, wherein:
the first device chip comprises at least one of a logic chip or a memory chip.

24. The method of claim 21, wherein:
the first device chip comprises a logic chip; and
the second device chip comprises a memory chip.

25. The method of claim 21, wherein:
a bump of the bump array comprises at least one of copper, nickel, or tin.

26. The method of claim 21, wherein:
the bump array comprises at least one of a flip chip bump, a Chip-on-Wafer-on-Substrate (CoWoS) micro-bump, or a controlled collapse chip connection (C4) bump.

27. The method of claim 21, wherein:
a first bump density of the first bump region is larger than a second bump density of the second bump region; and
the first bump density is smaller than a product of the second bump density and 1.15.

28. The method of claim 21, wherein:
a height of a bump of the bump array is between about 45 micrometers to about 65 micrometers.

29. The method of claim 21, wherein:
a bump coplanarity of the bump array is less than about 30 micrometers.

30. The method of claim 21, wherein:
bump sizes of bump regions of the bump array are linearly proportional to bump pitches of the bump regions.
